(19) United States
(12) Patent Application Publication
(10) Pub. No.: US 2009/0218559 A1
(43) Pub. Date: Sep. 3, 2009

(54) Integrated Circuit, Memory Cell Array, Memory Module, and Method of Manufacturing an Integrated Circuit

(76) Inventor: Ulrich Klostermann, Munich (DE)

Correspondence Address: SLATER & MATSIL, L.L.P., 17950 PRESTON ROAD, SUITE 1000, DALLAS, TX, 75252, US

(21) Appl. No.: 12/040,372

(22) Filed: Feb. 29, 2008

(51) Int. Cl. H01L 45/00; H01L 21/768

(52) U.S. Cl. 257/5; 438/675; 257/E45.002; 257/E21.586

(57) ABSTRACT

According to one embodiment of the present invention, an integrated circuit is provided including a plurality of magneto-resistive memory cells. Each memory cell includes a magnetic tunneling junction stack, wherein the top surfaces of the magnetic tunneling junctions stacks are electrically connected to a common continuous conductive plate.

### TECHNICAL FIELD

In various embodiments, the present invention relates to an integrated circuit, a memory cell array, a memory module, and a method of manufacturing an integrated circuit.

### BACKGROUND

Integrated circuits having magneto-resistive memory cells are known. Magneto-resistive memory cells involve spin electronics, which combines semiconductor technology and magnetics. The spin of an electron, rather than the charge, is used to indicate the presence of a “1” or “0”. One such spin electronic device is a magnetic random-access memory (MRAM), which includes conductive lines positioned perpendicular to one another in different metal layers, the conductive lines sandwiching a magnetic stack. The place where the conductive lines intersect is called a cross-point. A current flowing through one of the conductive lines generates a magnetic field around the conductive line and orients the magnetic polarity into a certain direction along the wire or conductive line. A current flowing through the other conductive line induces the magnetic field and can also partially turn the magnetic polarity. Digital information, represented as a “0” or “1” is stored in the alignment of magnetic moments. The resistance of the magnetic component depends on the moment's alignment. The stored state is read from the element by detecting the component's resistive state. A memory cell may be constructed by placing the conductive lines and cross-points in a matrix structure or array having rows and columns.

FIG. 1 illustrates a perspective view of a MRAM device 110 having bit lines 112 located orthogonal to word lines 114 in adjacent metallization layers. Magnetic stacks 116 are positioned between the bit lines 112 and word lines 114 adjacent and electrically coupled to bit lines 112 and word lines 114. Magnetic stacks 116 preferably include multiple layers, including a soft layer 118, a tunnel layer 120, and a hard layer 122, for example. Soft layer 118 and hard layer 122 preferably include a plurality of magnetic metal layers, for example, eight to twelve layers of materials such as PtMn, CoFe, Ru, and NiFe, as examples. A logic state is storable in the soft layer 118 of the magnetic stacks 116 located at the junction of the bitlines 112 and word lines 114 by running a current in the appropriate direction within the bit lines 112 and word lines 114 which changes the resistance of the magnetic stacks 116.

In order to read the logic state stored in the soft layer 118 of the magnetic stack 116, a schematic such as the one shown in FIG. 2, including a sense amplifier (SA) 230, is used to determine the logic state stored in an unknown memory cell MCu. A reference voltage U_{R} is applied to one end of the unknown memory cell MCu. The other end of the unknown memory cell MCu is coupled to a measurement resistor Rₘ₁ The other end of the measurement resistor Rₘ₁ is coupled to ground. The current running through the unknown memory cell MCu is equal to current I_{cell}. A reference circuit 232 supplies a reference current I_{ref}that is run into measurement resistor Rₘ₂. The other end of the measurement resistor Rₘ₂ is coupled to ground, as shown.

It is desirable to increase the reliability of integrated circuits having magneto-resistive memory cells.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a perspective schematic drawing of a part of an integrated circuit having magneto-resistive memory cells;

FIG. 2 shows a circuit useable in conjunction with the integrated circuit shown in FIG. 1;

FIG. 3 shows a schematic cross-sectional view of a part of an integrated circuit according to one embodiment of the present invention;

FIG. 4 shows a schematic cross-sectional view of a part of an integrated circuit according to one embodiment of the present invention;

FIG. 5 shows a schematic cross-sectional view of a part of an integrated circuit according to one embodiment of the present invention;

FIG. 6 shows a schematic cross-sectional view of a part of an integrated circuit according to one embodiment of the present invention;

FIG. 7 shows a schematic cross-sectional view of a part of an integrated circuit according to one embodiment of the present invention;

FIG. 8 shows a schematic cross-sectional view of a part of an integrated circuit according to one embodiment of the present invention;

FIG. 9 shows a flow chart of a method of manufacturing an integrated circuit according to one embodiment of the present invention;

FIG. 10A shows a schematic cross-sectional view of a processing stage of a method of manufacturing an integrated circuit according to one embodiment of the present invention;

FIG. 10B shows a schematic cross-sectional view of a processing stage of a method of manufacturing an integrated circuit according to one embodiment of the present invention;

FIG. 11A shows a schematic cross-sectional view of a processing stage of a method of manufacturing an integrated circuit according to one embodiment of the present invention;

FIG. 11B shows a schematic cross-sectional view of a processing stage of a method of manufacturing an integrated circuit according to one embodiment of the present invention;

FIG. 12A shows a schematic cross-sectional view of a processing stage of a method of manufacturing an integrated circuit according to one embodiment of the present invention;

FIG. 12B shows a schematic cross-sectional view of a processing stage of a method of manufacturing an integrated circuit according to one embodiment of the present invention;

FIG. 12C shows a schematic cross-sectional view of a processing stage of a method of manufacturing an integrated circuit according to one embodiment of the present invention;

FIG. 12D shows a schematic cross-sectional view of a processing stage of a method of manufacturing an integrated circuit according to one embodiment of the present invention;

FIG. 13A shows a schematic cross-sectional view of a processing stage of a method of manufacturing an integrated circuit according to one embodiment of the present invention;

FIG. 13B shows a schematic cross-sectional view of a processing stage of a method of manufacturing an integrated circuit according to one embodiment of the present invention;

FIG. 13C shows a schematic cross-sectional view of a processing stage of a method of manufacturing an integrated circuit according to one embodiment of the present invention;

FIG. 13D shows a schematic cross-sectional view of a processing stage of a method of manufacturing an integrated circuit according to one embodiment of the present invention;

FIG. 14A shows a schematic perspective drawing of a memory module according to one embodiment of the present invention; and

FIG. 14B shows a schematic perspective drawing of a memory module according to one embodiment of the present invention.

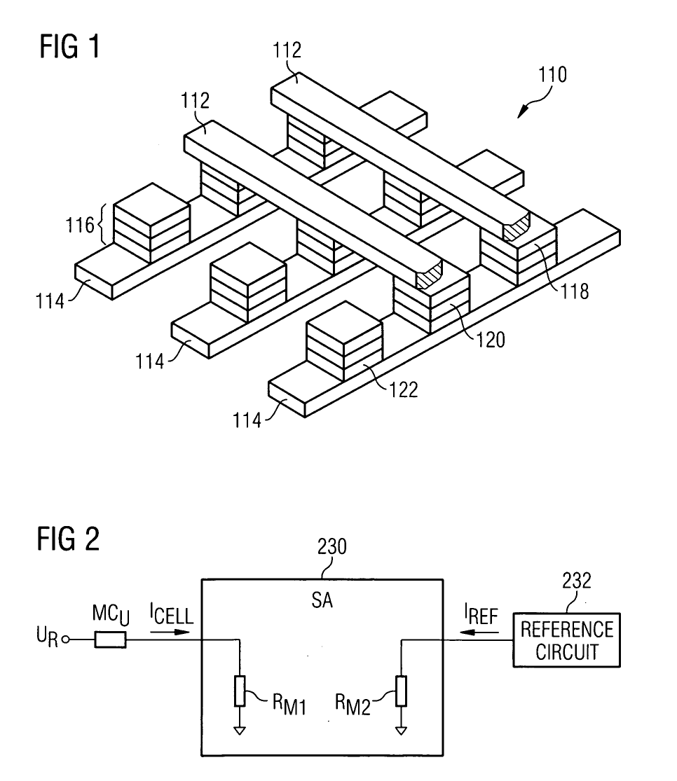

### DETAILED DESCRIPTION OF ILLUSTRATIVE EMBODIMENTS

According to one embodiment of the present invention, an integrated circuit comprising a plurality of magneto-resistive memory cells is provided, each memory cell comprising a magnetic tunnelling junction stack, wherein the top surfaces of the magnetic tunnelling junction stacks are electrically connected to a common continuous conductive plate.

According to one embodiment of the present invention, each memory cell is programmable by routing a programming current through the magnetic tunnelling junction stack of the memory cell.

According to one embodiment of the present invention, each memory cell is programmable using spin induced switching effects which are caused by the programming current.

According to one embodiment of the present invention, each memory cell is selectable using a select device which is located below the magnetic tunnelling junction stack of the memory cell.

According to one embodiment of the present invention, each select device is connected to two select lines which are arranged orthogonal to each other.

According to one embodiment of the present invention,the common conductive plate comprises magnetic material.

According to one embodiment of the present invention, the common conductive plate comprises a seed layer, a magnetic material layer, and a cap layer.

According to one embodiment of the present invention, the seed layer has a thickness ranging between about 5 nm to about 10 nm.

According to one embodiment of the present invention, the seed layer comprises or consists of Cu, CuN, Al, Ta, TaN, Ru, TiN, Ti, W, WN or a combination of these materials.

According to one embodiment of the present invention, the magnetic material layer has a thickness ranging between about 5 nm to about 300 nm.

According to one embodiment of the present invention, the magnetic material layer comprises or consists of Co, Ni, Fe, B, Tb, Zr, Ta, TaN, Ti, TiN, Ru, W, WN, Ag, Al, Ir, Mn, Pt or a combination of these materials.

According to one embodiment of the present invention, the cap layer has a thickness ranging between about 10 nm to about 50 nm.

According to one embodiment of the present invention, the cap layer comprises or consists of Cu, CuN, Al, Ta, TaN, Ru, TiN, Ti, W, WN or a combination of these materials.

According to one embodiment of the present invention, the magnetic material layer comprises a first ferromagnetic layer and an antiferromagnetic layer arranged on or below the first ferromagnetic layer.

According to one embodiment of the present invention, the antiferromagnetic layer is a natural antiferromagnetic layer.

According to one embodiment of the present invention, the magnetic material layer comprises a first ferromagnetic layer, a decoupling layer arranged on the first ferromagnetic layer, and a second ferromagnetic layer arranged on the decoupling layer.

According to one embodiment of the present invention, between the second ferromagnetic layer and the cap layer and/or between the first ferromagnetic layer and the seed layer, an antiferromagnetic layer is arranged.

According to one embodiment of the present invention, the antiferromagnetic layer comprises or consists of IrMn, FeMn, PtMn, NiMn, or a combination of these materials.

According to one embodiment of the present invention, the antiferromagnetic layer has a thickness ranging between about 2 nm to about 30 nm.

According to one embodiment of the present invention, the first ferromagnetic layer and the second ferromagnetic layer comprise or consist of Ni, Co, Fe, CoFeTb, NiFe, CoFe, PtCrCo, CoZrNb, CeFeB or a combination of these materials.

According to one embodiment of the present invention, the first ferromagnetic layer and the second ferromagnetic layer have thicknesses ranging between about 1 nm to about 200 nm.

According to one embodiment of the present invention, the decoupling layer comprises or consists of Ru, Cu, Rh, Ir, or a combination of these materials.

According to one embodiment of the present invention, the decoupling layer has a thickness ranging between about 0.5 nm to about 2 nm.

According to one embodiment of the present invention, the properties of the magnetic material layer are chosen such that the magnetic activation energy of the magnetic tunnelling junction stacks is increased.

According to one embodiment of the present invention, the common conductive plate is patterned into areas such that a magnetic interaction between the areas is reduced.

According to one embodiment of the present invention, between the areas, non-magnetic material is arranged.

According to one embodiment of the present invention, a memory cell array comprising a plurality of magneto-resistive memory cells is provided, each memory cell comprising a magnetic tunnelling junction stack, wherein the top surfaces of the magnetic tunnelling junction stacks are electrically connected to a common continuous conductive plate.

According to one embodiment of the present invention, a memory module comprising at least one integrated circuit comprising a plurality of magneto-resistive memory cells is provided, each memory cell comprising a magnetic tunnelling junction stack, wherein the top surfaces of the magnetic tunnelling junction stacks are electrically connected to a common continuous conductive plate.

According to one embodiment of the present invention, a method of manufacturing an integrated circuit is provided, comprising: providing a composite structure comprising a plurality of magnetic tunnelling junction stacks and an isolation layer covering the magnetic tunnelling junction stacks; patterning the isolation layer such that the top surfaces of the magnetic tunnelling junction stacks are exposed; providing a common continuous conductive plate on the composite structure such that the common continuous conductive plate is electrically connected to the top surfaces of the magnetic tunnelling junction stacks.

According to one embodiment of the present invention, the process of patterning the isolation layer comprises removing the complete isolation layer within a memory cell area of the composite structure.

According to one embodiment of the present invention,the process of patterning the isolation layer comprises forming contact holes within the isolation layer above the top surfaces of the magnetic tunnelling junction stacks until the top surfaces of the magnetic tunnelling junction stacks are exposed.

According to one embodiment of the present invention, the contact holes are filled with conductive material, wherein the common conductive continuous plate is provided on the composite structure such that the conductive material connects the common conductive continuous plate with the magnetic tunnelling junction stacks.

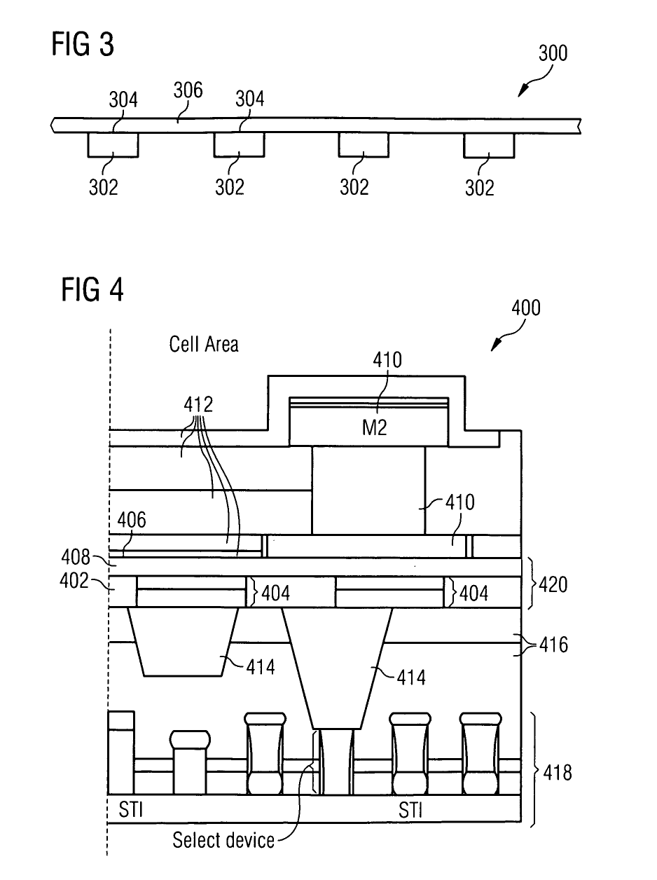

FIG. 3 shows a schematic cross-sectional view of a part of an integrated circuit 300 according to one embodiment of the present invention. The integrated circuit 300 includes a plurality of magneto-resistive memory cells, each memory cell including a magnetic tunneling junction stack 302, wherein the top surfaces 304 of the magnetic tunneling junction stacks 302 are electrically connected to a common continuous conductive plate 306.

According to one embodiment of the present invention, each memory cell is programmable by routing a programming current through the magnetic tunneling junction stack 302 assigned to the memory cell. According to one embodiment of the present invention, each memory cell is programmable using spin induced switching effects which are caused by the programming current.

According to one embodiment of the present invention, the memory cells are programmable spin torque cell which use a magnetization direction substantially parallel to the magnetic film (so called in-plane spin-torque magnetic memory cell) or perpendicular to the magnetic film (so called perpendicular spin-torque magnetic memory cell).

FIG. 4 shows a schematic cross-sectional view of a part of an integrated circuit 400 according to one embodiment of the present invention. The integrated circuit 400 includes an isolation layer 402 into which magnetic tunneling junction stacks 404 are embedded. The top surfaces 406 of the magnetic tunneling junction stacks 404 are contacted by (or electrically connected to) a continuous conductive plate 408 which is shared by all magnetic tunneling junction stacks, i.e. the continuous conductive plate 408 is electrically connected to all magnetic tunneling junction stacks 404. The continuous common conductive plate 408 is contacted by electric conductive elements 410 which are embedded into isolation layers 412. The magnetic tunneling junction stacks 404 are contacted from below by conductive elements 414 which are embedded into isolation layers 416. The integrated circuit 400 further includes a select device section 418 including several select devices which are used in order to select a particular magnetic tunneling junction stack 404, i.e., a particular memory cell. The select devices of the select device section 418 may, for example, be transistors which respectively are connected to two select lines.

One effect of the integrated circuit 400 is that it shows a relatively simple architecture, compared to conventional integrated circuits having magneto-resistive memory cells. Since spin induced current switching can be used in order to program the magnetic tunneling junction stacks 404, no bit lines which are isolated against each other have to be provided. The omission of bit lines which are isolated against each other also facilitates the manufacturing process of the integrated circuit 400 (less manufacturing steps and lower precision requirement during the generation of top contacts of the magnetic tunneling junction stacks 404).

FIG. 5 shows a schematic cross-sectional view of a part of an integrated circuit 500 according to one embodiment of the present invention. The integrated circuit 500 includes a conductive plate 408 which includes magnetic material. More exactly, the conductive plate 408 includes a seed layer 502, a magnetic material layer 504 arranged on the seed layer 502, and a cap layer 506 arranged on the magnetic material layer 504.

According to one embodiment of the present invention, the seed layer 502 has a thickness ranging between about 5 nm to about 10 nm.

According to one embodiment of the present invention, the seed layer 502 includes or consists of Cu, CuN, Al, Ta, TaN, Ru, TiN, Ti, W, WN or a combination of these materials.

According to one embodiment of the present invention, the magnetic material layer 504 has a thickness ranging between about 5 nm to about 300 nm.

According to one embodiment of the present invention, the magnetic material layer 504 includes or additionally consists of Co, Ni, Fe, B, Tb, Zr, Ta, TaN, Ti, TiN, Ru, W, WN, Ag, Al, Ir, Mn, Pt or a combination of these materials.

According to one embodiment of the present invention, the cap layer 506 has a thickness ranging between about 10 nm to about 50 nm.

According to one embodiment of the present invention, the cap layer 506 includes or consists of Cu, CuN, Al, Ta, TaN, Ru, TiN, Ti, W, WN or a combination of these materials.

According to one embodiment of the present invention, the magnetic material layer 504 includes a first ferromagnetic layer and a natural antiferromagnetic layer arranged on or below the first ferromagnetic layer.

According to one embodiment of the present invention, the magnetic material layer 504 includes a first ferromagnetic layer, a decoupling layer arranged on the first ferromagnetic layer, and a second ferromagnetic layer arranged on the decoupling layer. In this case, according to one embodiment of the present invention, a natural antiferromagnetic layer is arranged at least between the second ferromagnetic layer and the cap layer or between the first ferromagnetic layer and the seed layer.

According to one embodiment of the present invention, the natural antiferromagnetic layer includes or consists of IrMn, FeMn, PtMn, NiMn, or a combination of these materials.

According to one embodiment of the present invention, the natural antiferromagnetic layer has a thickness ranging between about 2 nm to about 30 nm.

According to one embodiment of the present invention, the first ferromagnetic layer and the second ferromagnetic layer comprise or consists of Ni, Co, Fe, CoFeTb, NiFe, CoFe, PtCrCo, CoZrNb, CeFeB, or a combination of these materials.

According to one embodiment of the present invention, the first ferromagnetic layer and the second ferromagnetic layer have thicknesses ranging between about 1 nm to about 200 nm.

According to one embodiment of the present invention, the decoupling layer includes or consists of Ru, Cu, Rh, Ir, or a combination of these materials.

According to one embodiment of the present invention, the decoupling layer has a thickness ranging between about 0.5 nm to about 2 nm.

According to one embodiment of the present invention, the properties (for example the thickness or the type of material) of the magnetic material layer 504 are chosen such that the magnetic activation energy of the magnetic tunneling junction stacks 404 is increased. When scaling down the sizes of the magnetic tunneling junction stacks 404, it may occur that the data retention of the magnetic tunneling junction stacks 404 is also reduced. In order to avoid this, magnetic material may be introduced into the conductive plate 408, as, for example, shown in FIG. 5 (magnetic material layer 504). One effect of the additional magnetic material is that the magnetic activation energy of the magnetic tunneling junction stacks 404 is increased, i.e., the magnetization within the magnetic tunneling junction stacks 404 is stabilized by the magnetization of the additional magnetic material (here: the magnetic material layer 504).

According to one embodiment of the present invention, the magnetic tunneling junction stacks 404 include the magnetic tunneling junction layer 508 and a magnetic tunneling junction cap or hard mask layer 510 arranged on the magnetic tunneling junction layer 508. The magnetic tunneling junction stacks 404 may include further layers.

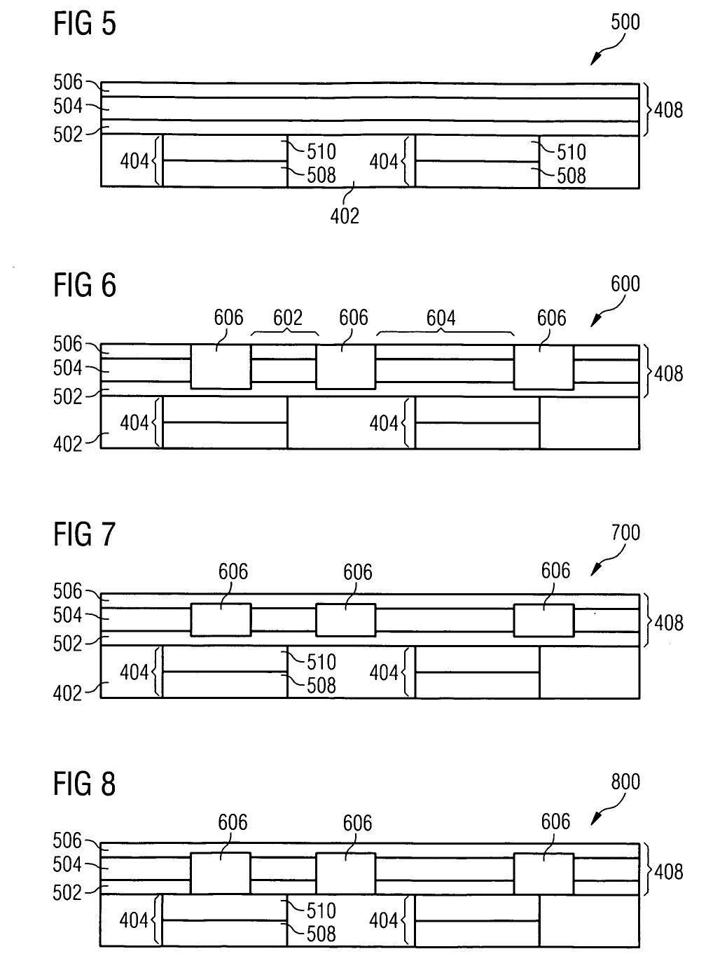

FIG. 6 shows a schematic cross-sectional view of a part of an integrated circuit 600 according to one embodiment of the present invention. The architecture of the integrated circuit 600 corresponds to the architecture of the integrated circuit 500 except of that the conductive plate 408 has been patterned. That is, the conductive plate 408 is divided into a plurality of regions including region 602 and region 604. Between regions 602 and 604, non-magnetic material 606 is arranged. One effect of the non-magnetic material 606 is that the magnetic interactions between different areas of the conductive plate 408, for example, a magnetic interaction between the areas 602 and 604, is altered. In this way, cross talk between the magnetizations of different areas of the conductive plate 408 can be reduced or avoided. In this way, magnetizations of the magnetic material layer 504 can be used in order to stabilize the magnetizations of the magnetic tunneling junction stacks 404 without having the risk that the magnetizations of the magnetic material layer 504 have undesired influence on magnetic tunneling junction stacks 404. For example, the magnetization of the area 602 may be used in order to stabilize the magnetization of the left magnetic tunneling junction stack 404; the magnetization of the area 604 may be used in order to stabilize the magnetization of the right magnetic tunneling junction stack 404. Due to the non-magnetic material 606 between the areas 602, 604 it is ensured that cross-talk between areas 602, 604 (and thus between the left and the right magnetic tunneling junction stacks 404) is avoided.

In order to manufacture the integrated circuit 600, contact holes may be formed within the conductive plate 408 which are then filled with non-magnetic material 606.

Within the integrated circuit 600, the contact holes which are filled with non-magnetic material 606 may reach from the top surface of the cap layer 506 into the seed layer 502, however do not reach the bottom surface of the seed layer 502 (FIG. 6). Alternatively, as shown in the integrated circuits 700 and 800 in FIGS. 7 and 8, the top surface of the non-magnetic material 606 may also be covered by the cap layer 506 (FIGS. 7 and 8). Further, the bottom surface of the non-magnetic material 606 may coincide with the bottom surface of the seed layer 502 (FIG. 8). Still alternatively (not shown), the bottom surface of the non-magnetic material 606 may coincide with the bottom surface of the seed layer 502, and the top surface of the non-magnetic material 606 my coincide with the top surface of the cap layer 506.

According to one embodiment of the invention, the non-magnetic material 606 can include or consist at least of a non-magnetic metal such as Tb, Zr, Ta, TaN, Ti, TiN, Ru, W, WN, Ag, Al, Ir, Pt or isolating materials such as Al₂O₃, SiO2 or SiN.

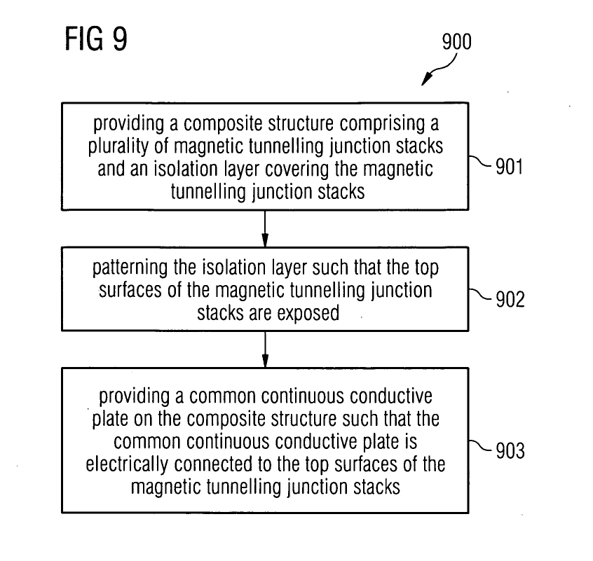

FIG. 9 shows a flow chart of a method 900 of manufacturing an integrated circuit according to one embodiment of the present invention. At 901, a composite structure is provided including a plurality of magnetic tunneling junctions stacks and an isolation layer covering the magnetic tunneling junction stacks. At 902, the isolation layer is patterned such that the top surfaces of the magnetic tunneling junction stacks are exposed. At 903, a common continuous conductive plate is provided on the composite structure such that the common continuous conductive plate is electrically connected to the top surfaces of the magnetic tunneling junction stacks.

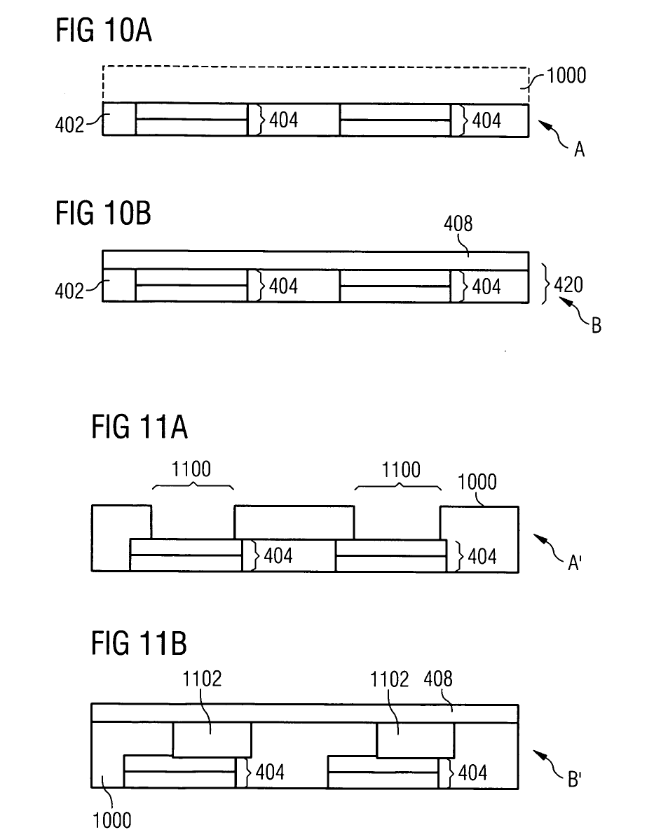

FIGS. 10A and 10B show a possible embodiment of the method 900 as disclosed above: FIG. 10A shows a manufacturing stage A of an integrated circuit obtained after having removed an isolation layer 1000 (indicated by dashed lines) which covers magnetic tunneling junction stacks 404 such that the top surfaces of the magnetic tunneling junction stacks 404 are exposed. The removal of the isolation layer 1000 may for example be carried out using a chemical mechanical polishing process (CMP process) or an planarization etch back process.

FIG. 10B shows a manufacturing stage B obtained after having provided a common continuous conductive plate 408 on the top surfaces of the magnetic tunneling junction stacks 404 and the top surfaces of an isolation layer 402 into which the magnetic tunneling junction stacks 404 are embedded. The structure which has been obtained in manufacturing process B may be the structure indicated by reference number 420 in FIG. 4.

FIGS. 11A and FIG. 11B show a further possible realization of the method 900 shown in FIG. 9: In a first manufacturing stage A′, contact holes 1100 are formed within an isolation layer 1000 into which magnetic tunneling junction stacks 404 are embedded. The contact holes are formed over the top surfaces of the magnetic tunneling junction stacks 404, wherein the depth of the contact holes is increased until the top surfaces of the magnetic tunneling junction stacks 404 are exposed.

In a second manufacturing stage B′ shown in FIG. 11B, the contact holes 1100 are filled with conductive material 1102. Then, a common continuous conductive plate 408 is provided on the top surface of the patterned isolation layer 1000 such that the conductive material 1102 electrically connects the common continuous conductive plate 408 with the top surfaces of the magnetic tunneling junction stacks 404.

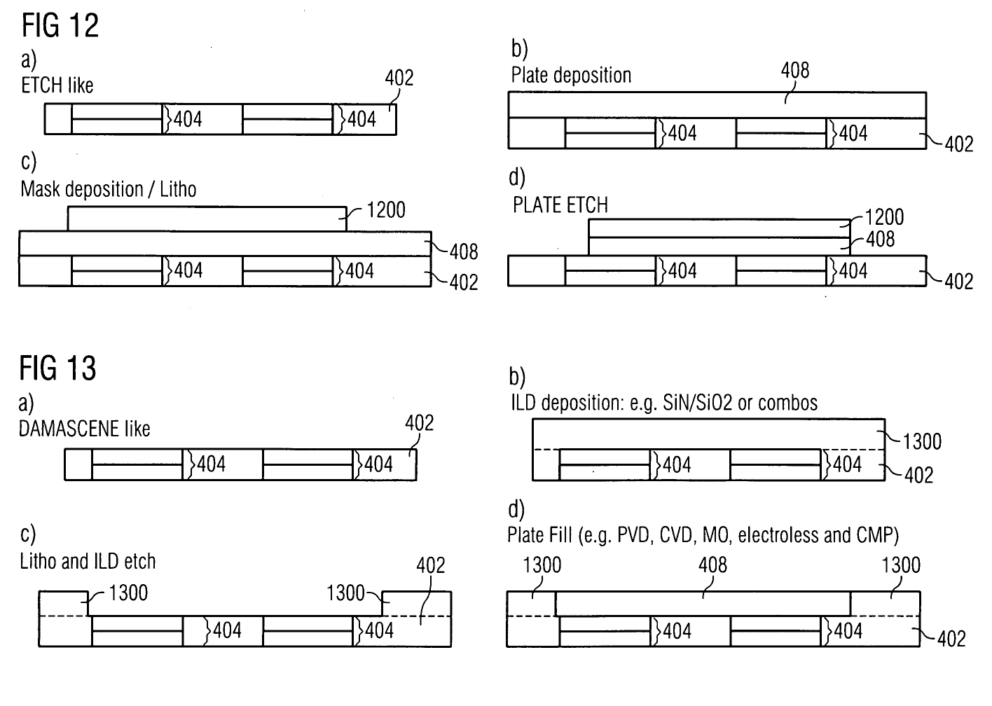

FIG. 12A to 12D show an embodiment how the common conductive plate 408 shown in FIGS. 10A and 11B may be patterned.

FIG. 12A shows the same manufacturing stage as already explained in conjunction with FIG. 10A. FIG. 12B shows the same manufacturing stage as explained in conjunction with FIG. 10B. FIG. 12C shows a manufacturing stage in which a mask layer 1200 has been provided on the common continuous conductive plate 408. The mask layer 1200 may, for example, be deposited on the whole top surface of the conductive plate 408. Then, after the deposition of the mask layer 1200, a lithographic process is carried out in order to pattern the mask layer 1200. FIG. 12D shows a processing stage obtained after having used the patterned mask layer 1200 as a mask for patterning the conductive plate 408. The patterning of the conductive plate 408 may for example be carried out using an etching process.

FIGS. 13A to 13D show an alternative way to pattern the common continuous conductive plate 408. FIG. 13A corresponds to the manufacturing stage shown in FIG. 12A. FIG. 13B shows a manufacturing stage in which an isolation layer 1300 has been deposited on the top surfaces of the magnetic tunneling junction stacks 404 and the isolation layer 402. FIG. 13C shows a manufacturing stage obtained after having patterned the isolation layer 1300 using, for example, a masking layer (not shown) which may be generated using a lithographic process. FIG. 13D shows a manufacturing stage obtained after having filled the removed part of the isolation layer 1300 with conductive material using, for example, a physical vapor deposition process (PVD), a chemical vapor deposition process (CVD) and following polishing processes (for example, CMP processes).

According to one embodiment of the present invention, the isolation layer 1300 may for example be a SiN layer, a SiO₂ layer, or a combination of these materials.

Isolation layer 1300 in contact to isolation layer 402 is used to improve manufacturability of the memory plate. Firstly, the pattering of the common plate will reduce mechanical stress build up of large common plate dimensions and secondly the isolation studs improve the adhesion of the common plate structure 420 as seen in FIG. 4 to underlying structures.

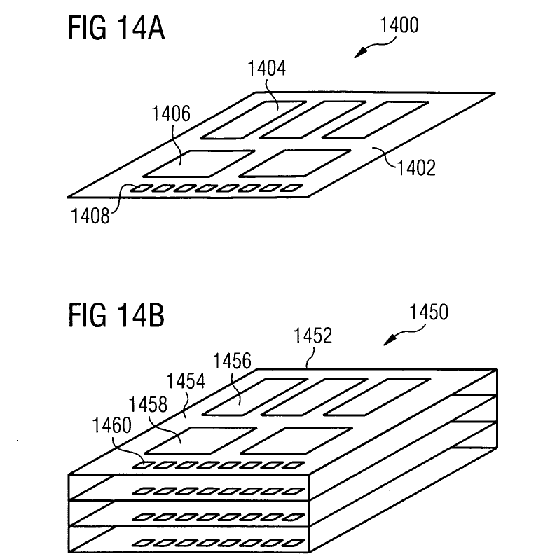

As shown in FIGS. 14A and 14B, in some embodiments, integrated circuits such as those described herein may be used in modules.

In FIG. 14A, a memory module 1400 is shown, on which one or more integrated circuits 1404 are arranged on a substrate 1402. The memory device 1404 may include numerous memory cells. The memory module 1400 may also include one or more electronic devices 1406, which may include memory, processing circuitry, control circuitry, addressing circuitry, bus interconnection circuitry, or other circuitry or electronic devices that may be combined on a module with a memory device, such as the integrated circuits 1404. Additionally, the memory module 1400 includes multiple electrical connections 1408, which may be used to connect the memory module 1400 to other electronic components, including other modules.

As shown in FIG. 14B, in some embodiments, these modules may be stackable, to form a stack 1450. For example, a stackable memory module 1452 may contain one or more integrated circuits 1456, arranged on a stackable substrate 1454. The integrated circuits 1456 contain memory cells. The stackable memory module 1452 may also include one or more electronic devices 1458, which may include memory, processing circuitry, control circuitry, addressing circuitry, bus interconnection circuitry, or other circuitry or electronic devices that may be combined on a module with a memory device, such as the integrated circuits 1456. Electrical connections 1460 are used to connect the stackable memory module 1452 with other modules in the stack 1450, or with other electronic devices. Other modules in the stack 1450 may include additional stackable memory modules, similar to the stackable memory module 1452 described above, or other types of stackable modules, such as stackable processing modules, control modules, communication modules, or other modules containing electronic components.

In the following description, further exemplary embodiments of the present invention will be explained.

It is known to select a MTJ cell by a bit line (BL) (on top of the MTJ stack) and a FET (field effect transistor) write word line. This approach implies: a complicated fabrication process for BL level due to tighter requirements for pattering (Litho, etch, etc.); a tight bit line alignment precision; a tight requirement for small BL feature sizes; the incorporation of additional magnetically functional layers into the BL is complicated or impossible.

According to one embodiment of the present invention, a common BL plate is used to contact all MTJs within an array from the top. This approach implies: self aligned bit line/plate formation; very relaxed bit line requirements for BL lithography; easy incorporation of additional functional magnetic layers into the BL contact for further write performance/activation energy enhancement.

New types of MRAM focus on the utilization of the spin induced current switching, where no magnetic field generation for writing the information is needed. In other words, the setting of the parallel and antiparallel resistance may be accomplished by driving a bidirectional writing current through the MTJ barrier. Hence, no BL and magnetic tunneling (MT) field generation lines are required as used in a conventional MRAM architecture. This facilitates the further shrinking and manufacturability of MRAM products due to less requirements for mask alignment precision and smaller feature sizes in the BEOL (back end of line) manufacturing part.

The scaling of small MTJ cells may be hindered by the decrease of the magnetic activation volume. It is essential to maintain a certain level of magnetic activation volume in order to avoid information loss during the product life time (e.g., 10 years). The use of a BL plate allows to magnetically couple the free layer magnetization volume to an extended magnetic active volume in the BL plate in order to increase the activation energy.

According to one embodiment of the present invention, the BL wiring on top of the MTJ stack is substituted by an extended plate.

According to one embodiment of the present invention, the BL plate includes at least magnetic active material to allow additional write performance features.

Within the scope of the present invention, the terms “connected” and “coupled” may both mean direct and indirect connecting/coupling.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising a plurality of magneto-resistive memory cells, each memory cell comprising a magnetic tunnelling junction stack, wherein top surfaces of the magnetic tunnelling junction stacks are electrically connected to a common continuous conductive plate.

2. The integrated circuit according to claim 1, wherein each memory cell is programmable by routing a programming current through the magnetic tunnelling junction stack of the memory cell.

3. The integrated circuit according to claim 2, wherein each memory cell is programmable using spin induced switching effects that are caused by the programming current.

4. The integrated circuit according to claim 1, wherein each memory cell is selectable using a select device that is located below the magnetic tunnelling junction stack of the memory cell.

5. The integrated circuit according to claim 4, wherein each select device is coupled to two select lines that are arranged orthogonally to each other.

6. The integrated circuit according to claim 1, wherein the common continuous conductive plate comprises magnetic material.

7. The integrated circuit according to claim 6, wherein the common continuous conductive plate comprises a seed layer, a magnetic material layer, and a cap layer.

8. The integrated circuit according to claim 7, wherein the seed layer comprises Cu, CuN, Al, Ta, TaN, Ru, TiN, Ti, W, WN or a combination of these materials.

9. The integrated circuit according to claim 7, wherein the magnetic material layer comprises Co, Ni, Fe, B, Tb, Zr, Ta, TaN, Ti, TiN, Ru, W, WN, Ag, Al, Ir, Mn, Pt or a combination of these materials.

10. The integrated circuit according to claim 7, wherein the cap layer comprises Cu, CuN, Al, Ta, TaN, Ru, TiN, Ti, W, WN or a combination of these materials.

11. The integrated circuit according to claim 7, wherein the magnetic material layer comprises a first ferromagnetic layer and an antiferromagnetic layer arranged on the first ferromagnetic layer.

12. The integrated circuit according to claim 7, wherein the magnetic material layer comprises a first ferromagnetic layer, a decoupling layer arranged on the first ferromagnetic layer, and a second ferromagnetic layer arranged on the decoupling layer.

13. The integrated circuit according to claim 12, wherein, an antiferromagnetic layer is arranged between the second ferromagnetic layer and the cap layer.

14. The integrated circuit according to claim 12, wherein the first ferromagnetic layer and the second ferromagnetic layer comprise Ni, Co, Fe, CoFeTb, NiFe, CoFe, PtCrCo, CoZrNb, CeFeB or a combination of these materials.

15. The integrated circuit according to claim 12, wherein the first ferromagnetic layer and the second ferromagnetic layer have thicknesses ranging between 1 nm to 200 nm.

16. The integrated circuit according to claim 12, wherein the decoupling layer comprises Ru, Cu, Rh, Ir, or a combination of these materials.

17. The integrated circuit according to claim 12, wherein the decoupling layer has a thickness ranging between 0.5 nm to 2 nm.

18. The integrated circuit according to claim 7, wherein the properties of the magnetic material layer are chosen such that magnetic activation energy of the magnetic tunnelling junction stacks is increased.

19. The integrated circuit according to claim 7, wherein the common continuous conductive plate is patterned into areas such that a magnetic interaction between the areas is reduced.

20. The integrated circuit according to claim 1, wherein, between areas, non-magnetic material is arranged.

21. A memory cell array comprising a plurality of magneto-resistive memory cells, each memory cell comprising a magnetic tunnelling junction stack, wherein top surfaces of the magnetic tunnelling junction stacks are electrically connected to a common continuous conductive plate.

22. A memory module comprising at least one integrated circuit comprising a plurality of magneto-resistive memory cells, each memory cell comprising a magnetic tunnelling junction stack, wherein the top surfaces of the magnetic tunnelling junction stacks are electrically connected to a common continuous conductive plate.

23. A method of manufacturing an integrated circuit, the method comprising:
providing a composite structure comprising a plurality of magnetic tunnelling junction stacks and an isolation layer covering the magnetic tunnelling junction stacks;
patterning the isolation layer such that top surfaces of the magnetic tunnelling junction stacks are exposed; and
providing a common continuous conductive plate on the composite structure such that the common continuous conductive plate is electrically connected to the top surfaces of the magnetic tunnelling junction stacks.

24. The method according to claim 23, wherein patterning the isolation layer comprises removing the complete isolation layer within a memory cell area of the composite structure.

25. The method according to claim 23, wherein patterning the isolation layer comprises forming contact holes within the isolation layer above the top surfaces of the magnetic tunnelling junction stacks until the top surfaces of the magnetic tunnelling junction stacks are exposed.

26. The method according to claim 25,
wherein the contact holes are filled with conductive material,
wherein the common conductive continuous plate is provided on the composite structure such that the conductive material connects the common conductive continuous plate with the magnetic tunnelling junction stacks.
